(19) United States
(12) Patent Application Publication
(10) Pub. No.: US 2015/0372296 A1
(43) Pub. Date: Dec. 24, 2015

(54) STRUCTURES INCLUDING ION BEAM-MIXED LITHIUM ION BATTERY ELECTRODES, METHODS OF MAKING, AND METHODS OF USE THEREOF

(71) Applicant: UNIVERSITY OF FLORIDA RESEARCH FOUNDATION, INC., Gainesville, FL (US)

(72) Inventors: Kevin S. JONES, Archer, FL (US); Nicholas G. RUDAWSKI, Gainesville, FL (US)

(21) Appl. No.: 14/379,949

(22) PCT Filed: Feb. 20, 2013
(86) PCT No.: PCT/US13/26806

§ 371 Date: Aug. 20, 2014

Related U.S. Application Data
(60) Provisional application No. 61/600,788, filed on Feb. 20, 2012.

(51) Int. Cl. H01M 4/38; H01J 37/317; H01M 4/66

(52) U.S. Cl. CPC H01M 4/38; H01M 4/381; H01M 4/661; H01M 4/386; H01M 4/669; H01J 37/3171; H01J 2237/31701

(57) ABSTRACT

Embodiments of the present disclosure provide for a structure, methods of making the structure, methods of using the structure, and the like. In an embodiment, the structure includes a film having one or more areas of the film being ion beam-mixed. In a particular embodiment, the structure includes a germanium film having one or more areas of the germanium film being ion beam-mixed.

### CLAIM OF PRIORITY TO RELATED APPLICATION

This application claims priority to co-pending U.S. provisional application entitled “STRUCTURES INCLUDING NANOSTRUCTURED ION BEAM-MODIFIED GERMANIUM ELECTRODES, METHODS OF MAKING, AND METHODS OF USE THEREOF” having Ser. No. 61/600,788, filed on Feb. 20, 2012, which is entirely incorporated herein by reference.

### BACKGROUND

Developing alternatives to currently commercially available Li ion battery (LIB) electrode materials remains of great importance. In particular, there is interest in Ge as an anode material due to the very high specific capacity (1623 mAh/g) and Li⁺ diffusivity. However, Ge experiences large volumetric changes of ˜400% during lithiation (charging) and delithiation (discharging). In nonporous thin film electrodes, this ultimately leads to intra-material fracture and/or delamination at the electrode/current collector interface, resulting in the loss of electrical contact and a concomitant decline in specific capacity with electrochemical cycling.

### SUMMARY

In accordance with the purpose(s) of the present disclosure, as embodied and broadly described herein, embodiments of the present disclosure, in one aspect, relate to a structure, methods of making the structure, methods of using the structure, and the like. In an embodiment, the structure includes a film having one or more areas of the film being ion beam-mixed.

In an embodiment the structure includes: a film disposed on the substrate, where one or more areas of the film have been ion beam-mixed to form an ion beam mixed film.

In an embodiment, the method of making a structure includes: providing a structure having a film disposed on a substrate; and forming an ion beam-mixed film by subjecting the film to ion beam implantation.

Other systems, methods, features, and advantages will be, or become, apparent to one with skill in the art upon examination of the following drawings and detailed description. It is intended that all such additional structures, systems, methods, features, and advantages be included within this description, be within the scope of the present disclosure, and be protected by the accompanying claims.

### BRIEF DESCRIPTION OF THE DRAWINGS

Many aspects of this disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates HR-XTEM images showing the effect of ion beam modification on the morphology of deposited Ge electrodes: FIG. 1(a) as-deposited and FIG. 1(b) ion beam-modified using Ge⁺-implantation at T=77 K with energy of 260 keV and dose of 1.0×10¹⁶ cm⁻². Also shown is the implanted Ge⁺ distribution calculated using the Monte Carlo SRIM-code. FIG. 1(c) illustrates the load versus depth curves for virgin as-deposited and ion beam-mixed Ge electrodes subjected to nanoindentation testing. The as-deposited electrode exhibits a distinct excursion in the load curve at an indentation depth of ˜150 nm while the ion beam-mixed electrode exhibits no such excursion, indicating the ion beam-mixed electrode has enhanced strength of adhesion.

FIG. 2 illustrates the electrochemical cycling data for Ge electrodes: FIG. 2(a), voltage curves for cycles 1, 2, and 25 of an ion beam-mixed electrode galvanostatically cycled at a 0.4 C rate, FIG. 2(b), cyclic voltammograms (sweep rate of 1 mV s⁻¹) for cycles 1 and 64 of an ion beam-mixed electrode, FIG. 2(c), cycle life plot for as-deposited and ion beam-mixed electrodes galvanostatically cycled at a 0.4 C rate for 25 cycles, and FIG. 2(d), cycle life plot for as-deposited and ion beam-mixed electrodes galvanostatically cycled sequentially at 0.2 C, 0.4 C, 0.8 C, 1.6 C, and 0.2 C for 5 cycles each (25 cycles total).

FIG. 3 illustrates the morphological evolution of ion beam-mixed Ge electrodes galvanostatically cycled at a 0.4 C rate. FIGS. 3(a-d) illustrate the top-down SEM images of electrodes after 0, 1, 12, and 25 cycles, respectively. FIGS. 3(e-h) illustrate HR-XTEM images of electrodes after 0, 1, 12, and 25 cycles, respectively; the protective C/Pt layers, Ge film, and Ni—Fe foil substrate are indicated.

FIG. 4 illustrates high-magnification HR-XTEM images showing the generation of a porous microstructure in ion beam-mixed Ge electrodes due to electrochemical cycling: FIG. 4(a) virgin electrode and FIG. 4(b) an electrode galvanostatically cycled at 0.4 C rate for 25 cycles. Both images were taken with defocus Δf˜−1000 nm to highlight the presence of any pores.

### DETAILED DESCRIPTION

Before the present disclosure is described in greater detail, it is to be understood that this disclosure is not limited to particular embodiments described, as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed. Terms defined in references that are incorporated by reference do not alter definitions of terms defined in the present disclosure or should such terms be used to define terms in the present disclosure they should only be used in a manner that is inconsistent with the present disclosure.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Embodiments of the present disclosure will employ, unless otherwise indicated, techniques of chemistry, inorganic chemistry, material science, and the like, which are within the skill of the art. Such techniques are explained fully in the literature.

The following examples are put forth so as to provide those of ordinary skill in the art with a complete disclosure and description of how to perform the methods and use the compositions and compounds disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is in atmosphere. Standard temperature and pressure are defined as 25° C. and 1 atmosphere.

Before the embodiments of the present disclosure are described in detail, it is to be understood that, unless otherwise indicated, the present disclosure is not limited to particular materials, reagents, reaction materials, manufacturing processes, or the like, as such can vary. It is also to be understood that the terminology used herein is for purposes of describing particular embodiments only, and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

### Discussion

Embodiments of the present disclosure provide for a structure, methods of making the structure, methods of using the structure, and the like. In an embodiment, the structure includes a film having one or more areas of the film being ion beam-mixed. In a particular embodiment, the structure includes a germanium film having one or more areas of the germanium film being ion beam-mixed.

In an embodiment, ion implantation can be used to ion beam mix the interface between deposited films for active cathodes and anodes and the metallic electrode in order to improve the adhesion and thus the cycling behavior of the battery. Silicon and germanium are known to be excellent candidates for anodes in Li ion batteries. However due to the large volume expansion these films will delaminate from the metal electrode surface resulting in loss of electrical contact and fading of the battery capacity upon cycling. By implanting ions through the interface it is possible to improve the adhesion of the thin film to the metallic substrate by ion beam mixing. This improved adhesion leads to improved cycling of these materials and significantly less fading of the battery capacity upon cycling. A similar behavior is expected for cathodes as well. For example FeFₓ alloys (where x is 2 to 3) are promising cathode materials. These materials also suffer from volumetric expansion upon lithiation. Ion beam mixing of the cathode current collector should result in a similar behavior as the ion beam mixed anode materials.

In an embodiment the structure can be used as an anode in a lithium ion battery, used in a capacitor structure or a photovoltaic cell. An advantage of using the structure in a lithium ion battery includes improved electrochemical cycling characteristics by decreasing the capacity fade. In addition, the ion beam-mixed germanium and silicon electrodes maintain excellent electrical contact with the current collector substrate.

In an embodiment, the film of material can be a germanium film or a film made of another type of material such as silicon, silicon-germanium alloys, FeFₓ alloy, sulfur film, sulfur compound based film, vandium based oxide film, a MF_{x.} film, where M=Fe, Cu, Na, x is 1 to 3, or other materials that can be used in battery electrodes. In an embodiment, the film can be a combination of materials. In an embodiment, the film can have a thickness of about 100 nm to 2000 nm. In an embodiment where the film is germanium, one can add or change a characteristic of the germanium film by including other materials in the germanium layer. For example, inclusion of silicon in the germanium film can increase the specific capacity (mAh/g) of the film. In addition to changing the specific capacity of the electrode, electrochemical rates can also be tailored through the implementation of silicon in the microstructure.

In an exemplary embodiment, the structure includes a substrate having a film of material such as a germanium film disposed on the substrate. In an embodiment, the germanium film can be created by electron beam evaporation, for example. In an embodiment, the germanium film can have a thickness of about 100 nm to 2000 nm. In an embodiment, the germanium film can be substituted with germanium-silicon film or silicon film.

In an embodiment, the substrate can be a material such as Al, Ni, Fe, Cu, stainless steel, or a non-lithiating material or metal that is used as an electrode substrate for lithium-ion battery cells. In an embodiment, the phrase “non-lithiating material” means a material that does not chemically react or store Li during electrochemical cycling. In a particular embodiment, the substrate can be Ni or can be a Ni/Fe foil (about 80%/20%). In an embodiment, the substrate can have a thickness as needed for the particular application. In an embodiment, the substrate can have a thickness of about 0.2 μm to 5 mm or about 25 μm to 500 μm.

In an embodiment, a structure including the ion beam mixed film (e.g., ion beam-mixed germanium film) has enhanced characteristics relative to a similar structure that has not been exposed to ion implantation (e.g., Ge⁺ ion implantation) and therefore, does not include an ion beam-mixed film. In an embodiment, the ion beam mixed film includes the deposited electrochemically active material, the metallic current collector and/or any internal interface that is intermixed as a result of the ion bombardment process. The ion beam mixing process occurs when the energetic ion beam passes through the interface. The ion beam range into most materials is about 0.01 μm and 10 μm, so the thickness of the ion beam mixed film may fall within this range. To apply ion beam mixing to films thicker than the ion range, it is possible to deposit a thinner film of active material. Then, one can subject the thinner film to ion implantation to ion beam mix the interface. Subsequently deposit additional material to increase the cathode or anode capacity to the desired value.

The following method of making is directed to a substrate having a germanium film and using Ge⁺ ion implantation. However, the same general method can be used for other material films and ion implantation techniques. In an embodiment, the method for forming the structure that includes the substrate having the germanium film, for example, disposed on the substrate can include providing a substrate, such as one of those described herein. In an embodiment, a film of germanium can be formed on the substrate through evaporation, sputtering, or chemical vapor deposition of the germanium. Subsequently in an embodiment, one or more areas of the germanium film are subjected to ion implantation (e.g., Ge⁺ ion implantation) to form the ion beam mixed germanium film.

In an embodiment, the ion beam used may be any ion (anion or cation) in the periodic table (e.g., Ge⁺) with heavier ions in general resulting in greater mixing. In an embodiment, the implant energy can be about 1 keV to 10 MeV (e.g., 260 keV) and is tailored to the thickness of the deposited film. In an embodiment, the ion dose can be about 1.0×10¹³ to 1.0×10¹⁷ cm⁻² (e.g. 1.0×10¹⁶ cm⁻²) with a general improvement in adhesion and thus cycling behavior observed with increasing dose. In an embodiment, the implant temperature can be about 77 to 600 K depending on the reaction of the deposited film to the implantation process. In an embodiment, the ion implantation temperature can be a temperature above the melting of the materials of the structure or at a temperature so that the materials of the structure are not degraded. In an embodiment, the ion implantation can have tilt angle and/or twist angle of about 0 to ±90 degrees. It should be noted that the specific ion energy, ion dose, temperature, tilt angle, and twist angle, can depend, at least in part, upon the ions, the substrate, and the like.

In an embodiment, each area can be a few nanometers to micrometers to centimeters across the area and can be several hundred cm². In an embodiment, the area can be polygonal, circular, or the like. In an embodiment, once the ion beam-mixed germanium film is made, the germanium film can be modified (e.g., made porous, and the like).

Although not intending to be bound by theory, the implantation process may increase the adhesion of the germanium film to the substrate, and the Ge implantation may alter the evolution of the germanium film upon battery cycling such as to reduce the fading associated with film delamination. Additional details are provided in the Example.

### EXAMPLE

Now having described the embodiments of the disclosure, in general, the examples describe some additional embodiments. While embodiments of the present disclosure are described in connection with the example and the corresponding text and figures, there is no intent to limit embodiments of the disclosure to these descriptions. On the contrary, the intent is to cover all alternatives, modifications, and equivalents included within the spirit and scope of embodiments of the present disclosure.

### Example 1

### Brief Introduction

Ion beam modification to effect ion beam mixing without changing morphology was investigated as a means to improve the electrochemical performance of Ge thin film electrodes for rechargeable Li batteries. As a result of a minimum tenfold increase in the strength of adhesion of the Ge film to the current collector (substrate), the ion beam-mixed electrodes exhibited stable specific capacities of ˜1500 mAh (close to the theoretical maximum of 1623 mAh g⁻¹) for galvanostatic cycling rates of 0.2 C-1.6 C using both single- and multi-rate testing schemes. Electron microscopy investigations showed that the ion beam-mixed electrodes transform from a flat, continuous, nonporous microstructure in the virgin state to a rough, cracked, porous microstructure as a result of electrochemical cycling, but remain in excellent electrical contact with the current collector. The results suggest that ion beam mixing could be used to produce inexpensive, high capacity conversion electrodes for rechargeable Li batteries.

### Introduction:

There is great interest in the use of conversion (or synthesizing) electrodes like Si, Ge, and Sn for Li ion battery anodes, which have very large specific capacities 3-11 times that of the traditional graphite intercalation anode [1-3]. However, conversion electrodes experience very large volumetric changes on the order of 300-400% as a result of lithiation (charging) and delithation (discharging). In film electrodes, this can result in material losing electrical contact due to intra-material fracture and/or delamination at the electrode/current collector interface with a concomitant decrease in electrode capacity with prolonged electrochemical cycling [4]. Typically, addressing the challenge of accommodating the large volumetric changes that occur during cycling of conversion electrodes without material decrepitation has centered on altering the morphology of the electrode[5]. Specifically, it has been shown that conversion electrodes with nanoscale features are able to facilitate stress relaxation during electrochemical cycling without intra-material fracture [6-11]. However, this approach has limitations in terms of practical applicability due to cost, difficulty of fabrication, and total electrode capacity. Furthermore, the approach of altering electrode morphology does not directly address the other major decrepitation mechanism associated with the integrity of the interface between the electrode and current collector.

In principle, the ability of a film electrode to maintain electrical contact with the current collector during electrochemical cycling is directly related to the adhesion strength (also known as work of adhesion) between the film and substrate [12-14]. Therefore, all other factors being equal, an electrode with greater adhesion strength should be more resistant to cycling-induced decrepitation and should therefore exhibit superior performance. One well-known method to enhance the adhesion strength of a film to a substrate is by ion beam modification [15-17]. Specifically, it has been shown that ion beam mixing, or atomic-level intermixing between the film and substrate by energetic ion bombardment, can enhance adhesion strength by up to two orders of magnitude [18-20]. Recently, it was shown that ion beam modification of Ge film electrodes resulted in a dramatic improvement in electrochemical performance compared to as-prepared electrodes and it was speculated that ion beam mixing might have been a contributing factor [21]. However, it was not possible to isolate the exact role of ion beam mixing on electrochemical performance since the room-temperature ion beam modification step also effected a dramatic change in the morphology of the electrode, which is well known for ion-implanted Ge [22-29]. In this work, it is shown for the first time that ion beam mixing of a conversion electrode/current collector interface results in a significant improvement in the electrochemical performance of the electrode. This improvement is the result of increased adhesion of the Ge film to the current collector and not any change in film morphology.

### EXPERIMENTAL

Ge electrodes were produced by depositing a 140 nm-thick Ge film onto a 10×10 cm² area of McMaster-Carr 0.005 cm-thick 80 at % Ni-20 at % foil substrate using room-temperature electron beam evaporation at a rate of 0.5 nm s⁻¹ using an s-type Ge target with dopant concentration of 1.0×10¹⁷ cm⁻³. A portion of this “as-deposited” electrode material was then subjected to ion beam modification at a temperature of 77 K using Ge⁺ implantation at an energy of 260 keV and dose of 1.0×10¹⁸ cm⁻² to produce “ion beam-modified” electrodes and to effect ion beam mixing of the Ge/substrate interface without altering the morphology of the Ge film [29]. The adhesion strength of the films was studied by performing nanoindentation using a Hysitron Triboindenter equipped with a cube corner tip and by performing scotch tape [30] testing.

Cells for electrochemical testing were prepared in sealed pouches in an Ar atmosphere (H₂O concentration <0.9 ppm) using 50 μm-thick polypropylene separators and 1.0 M LiPF₆ in 1:1 (by volume) ethylene carbonate:dimethyl carbonate (DMC) liquid electrolyte [31] with the Ge film on the Ni—Fe foil as one electrode and Li metal foil as the other electrode (half-cell configuration). The electrochemical properties of the electrodes were evaluated with galvanostatic (constant current) cycling and cyclic voltammetry (voltage sweep rate of 1 mV s⁻¹) using an Arbin BT2000 battery tester. The voltage range for both types of cycling was 0.01 to 1.50 V as used in other Ge studies [7, 32-36]. In the case of galvanostatic cycling, the charge/discharge currents needed to generate the specified cycling rates for each sample were calculated by estimating the Ge mass of each sample using the reported density [37] of evaporated Ge (4.82 g cm⁻³), the surface area of the electrode, and the 140 nm thickness of the as-deposited films; the typical surface area for an electrode used in this work was ˜5×5 mm² with typical charge and discharge currents ranging from 5-30 μA (depending on the cycling rate). The estimated experimental error in all mass calculations was ±5%, which results in a corresponding experimental error of the same magnitude for all reported specific capacities. Additionally, loss of Ge mass due to sputtering as a result of ion beam modification is expected to be negligible (<1%) as per simulations [38]; the additional Ge mass resulting from ion beam modification is also negligible (<0.001%). The morphological and structural evolution of the electrodes was evaluated ex-situ with high-resolution cross-sectional transmission electron microscopy (HR-XTEM) using a JEOL 2010F transmission electron microscope and top-down scanning electron microscopy (SEM) using an FEI DB235 dual beam scanning electron microscope/focused ion beam (FIB) system; FIB milling was used to prepare HR-XTEM samples. Prior to FIB processing, samples were coated with a protective C layer while protective Pt layers were deposited in-situ during FIB processing to prevent surface damage. Prior to analyzing cycled electrodes, the cells were reintroduced into the Ar environment used for fabrication and the electrodes given a 1 min wash with DMC to remove remnant electrolyte [39]. Care was taken to minimize exposure of cycled electrodes to air prior to HR-XTEM or SEM analysis.

### Results and Discussion:

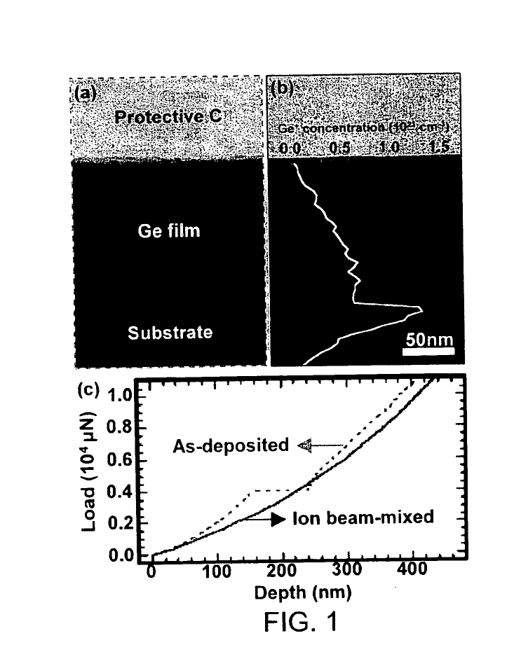

FIGS. 1(a) and (b) present HR-XTEM images comparing the morphology of virgin as-deposited and ion beam-mixed Ge electrodes, respectively. The Ge electrodes are ˜140 nm-thick with no detectable difference in film morphology evident between as-deposited and ion beam-modified electrodes, consistent with prior reports of ion beam-modification of Ge under similar conditions used in this work [29]. The virgin as-deposited and ion beam-mixed electrodes were also amorphous, as confirmed using selected area electron diffraction (not presented). The distribution of implanted Ge⁺ was calculated using the SRIM-Monte Carlo code [38] and is superimposed on FIG. 1(b). This code also predicts ˜5 nm of intermixing at the electrode/current collector interface as a result of ion beam modification.

Nanoindentation was used to investigate the effect of ion beam modification on electrode adhesion strength as shown in the load versus depth curves presented in FIG. 1(c). In the case of the as-deposited electrode, there is a distinct discontinuity in the loading curve at an indentation depth of ˜150 nm (close to the measured film thickness), which is consistent with delamination of the film from the substrate [40]. Comparatively, the ion beam-mixed electrode did not exhibit any such excursions, indicating no delamination during nanoindentation and confirming the adhesion strength of the ion beam-mixed electrode to be significantly higher than that of the as-deposited counterpart. The enhanced adhesion strength of the ion beam-mixed electrodes was also confirmed using scotch tape testing [30], which resulted in complete delamination of the as-deposited film while the ion beam-mixed film did not delaminate. Based on the results from nanoindentation and scotch tape testing in conjunction with prior work using these methods to quantify film adhesion [30, 40], reasonable limits on the adhesion strength of as-deposited and ion beam-mixed electrodes are estimated at <1 and >10 J m⁻², respectively, indicating a minimum tenfold increase in adhesion strength due to ion beam modification.

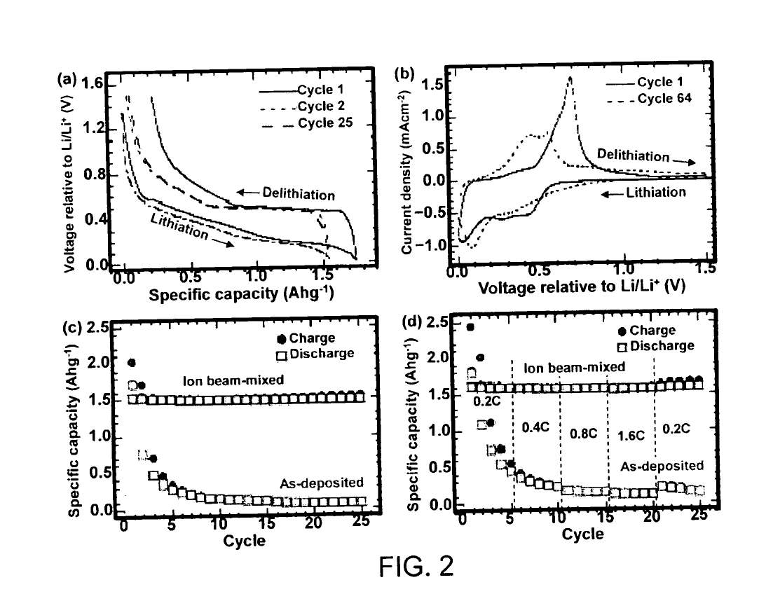

FIG. 2(a) shows the voltage curves for cycles 1, 2, and 25 of an ion beam-mixed Ge electrode subjected to galvanostatic cycling at a 0.4 C rate (2.5 h per charge or discharge). The specific charge (discharge) capacity for cycle 1 was 1730 (1527) mAh g⁻¹ indicating a Coulombic efficiency of 88.3% and suggesting the formation of a solid-electrolyte interphase layer [41]. For the subsequent second cycle, the specific charge (discharge) capacity was 1547 (1515) mAh g⁻¹ with a coulombic efficiency of ˜97.9%. The voltage curve for cycle 25 was nearly identical that of cycle 2, with a specific charge (discharge) capacity of 1540 (1486) mAh g⁻¹ and a coulombic efficiency of ˜96.5% suggesting virtually no capacity fade over 25 cycles. All three voltage curves share similar features, most notably the distinct plateau at ˜0.50 V during delithiation, which are consistent with reported voltage curves for the electrochemical cycling Ge with Li [7, 32-36]. Additionally, ion beam-mixed electrodes cycled at 0.2 C, 0.8 C, and 1.6 C rates for 25 cycles exhibited basically identical voltage curves for cycles 1, 2, and 25 compared to the case of cycling at a 0.4 C rate (Supplementary data). FIG. 2(b) presents cyclic voltammograms for cycles 1 and 64 of an ion beam-mixed Ge film collected with a voltage sweep rate of 1 mV s⁻¹. During cycle 1, there were distinct cathodic peaks at voltages of ˜0.41, 0.27, and ˜0.028 V with a single distinct anodic peak at ˜0.69 V. After 64 cycles, a single distinct cathodic peak was evident at a voltage of ˜0.082 while two distinct anodic peaks were observed at voltages of ˜0.44 and ˜0.55 V. The shifting in the voltages at which peaks were observed is consistent with prior reports of cyclic voltammetry of conversion electrode materials and has been attributed to cycling-induced changes in electrode morphology [6]. Similarly to the voltage curves, the reported cyclic voltammetry data is consistent with previous reports of electrochemical cycling of Ge with Li [32].

FIG. 2(c) presents cycle life behavior for as-deposited and ion beam-mixed Ge electrodes cycled at a 0.4 C rate. The specific capacity of the as-deposited electrode faded very rapidly with cycling with specific charge and discharge capacities of ˜75 mAhg⁻¹ after 25 cycles, which indicates the loss of electrical contact of active material as a result of cycling. In contrast, the ion beam-mixed electrode exhibited virtually no capacity fade over 25 cycles with stable specific charge and discharge capacities of ˜1500 mAhg⁻¹ and coulombic efficiencies greater than 96.5%. This indicates no loss of electrical contact of active material with cycling and shows a remarkable ˜2000% improvement in performance compared to the as-deposited electrode. Additionally, ion beam-mixed electrodes were also cycled at 0.2 C, 0.8 C, and 1.6 C rates for 25 cycles and exhibited virtually no capacity fade over 25 cycles with stable specific charge and discharge capacities of ˜1500 mAh g⁻¹, very similar to the case of cycling at a 0.4 C rate shown in FIG. 2(c). Additionally, as-deposited and ion beam-mixed electrodes were also subjected to galvanostatic cycling at a 1.6 C rate for 200 cycles. The specific charge and discharge capacities of the as-deposited electrode faded rapidly to ˜60 mAh g⁻¹ after 200 cycles. In comparison, the ion beam-mixed electrode exhibited capacity fading, but the specific charge and discharge capacities were still ˜650 mAh g⁻¹, which is an improvement of ˜900% compared to the as-deposited electrode.

FIG. 2(d) shows the cycle life performance of as-deposited and ion beam-mixed electrodes subjected to galvanostatic cycling sequentially at 0.2 C, 0.4 C, 0.8 C, 1.6 C, and 0.2 C for 5 cycles each (25 cycles total). The as-deposited electrode showed dramatic capacity fading with specific charge and discharge capacities of ˜120 mAh g⁻¹ observed at a 1.6 C rate; upon returning the cycling rate to 0.2 C, specific charge and discharge capacities of only ˜150 mAh g⁻¹ were retained, which again indicates the loss of electrical contact of active material. The ion beam-mixed electrode subjected to the same cycling scheme showed virtually no capacity fade even at a cycling rate of 1.6 C with stable specific charge and discharge capacities >1500 mAh g⁻¹. Upon returning the cycling rate to 0.2 C, the specific charge and discharge capacities remained stable and >1500 mAh g⁻¹, which indicates no loss of electrical contact of active material as a result of cycling. The lack of capacity fading with increasing cycling rate using multi-rate and single-rate cycling schemes is particularly noteworthy, since other types of Ge electrodes subjected to similar cycling schemes exhibited pronounced decreases in specific capacity with increasing cycling rate [7, 34, 42]. Moreover, the electrochemical performance of the ion beam-mixed Ge electrodes is among the best reported for any type of Ge electrode. In particular, the performance is superior to many nanoscale forms of Ge electrodes including nanoparticle composites [8, 35], nanowires [7, 10], and nanotubes [42, 43].

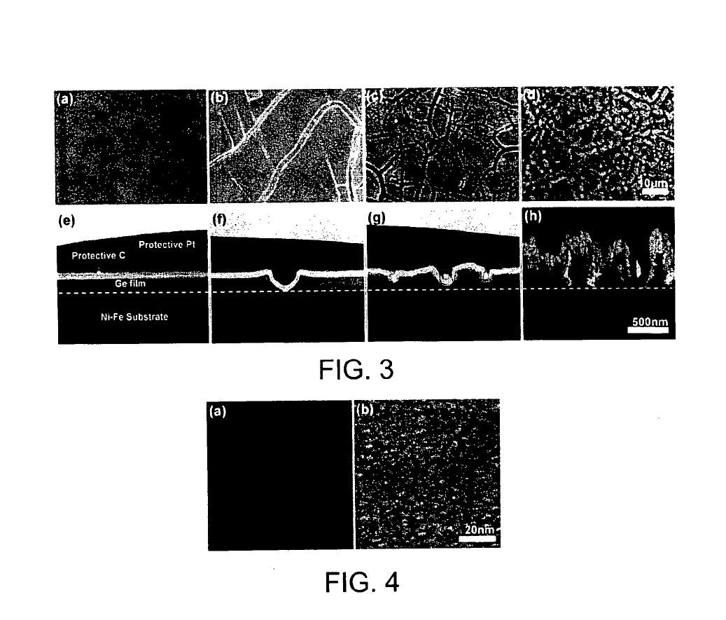

SEM and HR-XTEM were used to investigate the microstructure of ion beam-mixed Ge electrodes subjected to galvanostatic cycling at a 0.4 C rate as shown in FIG. 3. FIGS. 5(a) and (e) are images of an as-irradiated electrode, showing that it initially exhibits a basically featureless surface and uniform thickness. After 1 cycle, the surface exhibits through-film cracking, as shown in FIG. 3(b), but the electrode remains relatively flat, with ˜200 nm peak-to-valley roughening in the vicinity of cracks, as shown in FIG. 3(f). With further cycling to 12 cycles, the crack density increases, as shown in the FIG. 3(c), and the morphology of the electrode transforms into three-dimensional islands with ˜300 nm peak to valley roughening, as shown in FIG. 3(g). After 25 cycles there is no further change in crack density but the peak-to-valley roughening increases to ˜750 nm and the three-dimensional islands extend further above and below the original surface plane, as shown in FIG. 3(h). High-magnification HR-XTEM was also performed on the ion beam-mixed Ge electrodes to study the nanoscale morphological evolution during cycling, as shown in FIG. 4. The virgin electrode was found to be bulk-like with little evidence for porosity, as shown in FIG. 4(a). However, an electrode subjected to galvanostatic cycling at a 0.4 C rate for 25 cycles, was found to be highly porous, with pores ˜5 nm in diameter evident throughout the material, as shown in FIG. 4(b).

The through-film crack evolution observed for the ion beam-mixed Ge electrodes is very similar to crack evolution reported in other types of thin film conversion electrodes [12, 13]. However, the dramatic structural evolution from a continuous flat film to a three-dimensional porous microstructure has not been observed for other thin film conversion electrodes. It is interesting to note, however, that NW forms of conversion electrodes have been show to develop porosity upon electrochemical cycling [44]; a change attributed to long-range rearrangement and transport of atoms in the material during the insertion and removal of Li (characteristic of conversion electrodes). It has also been shown that the porosity of the NWs increases with the number of electrochemical cycles [44], which is very similar to the morphological evolution observed for the ion beam-mixed Ge electrodes presented in FIGS. 3 and 4. In the case of NW electrodes, the small diameters [4] allow the NWs to survive a large number of electrochemical cycles without decrepitation [6, 7, 45], which explains the observation of increasing porosity with prolonged electrochemical cycling (i.e. premature failure of the electrodes precludes the observation of such structural evolution). Similar arguments can be used to explain the structural evolution of ion beam-mixed Ge electrodes.

As a result of this morphological evolution, the ion beam-mixed electrodes acquire a very high surface area to volume ratio, which should facilitate faster Li insertion and extraction during cycling [5]. This explains why there is virtually no fade in the specific capacity of the ion beam-mixed electrodes over 25 cycles for a range of cycling rates as shown in FIGS. 3 and 4, which has not been reported for other types of Ge film electrodes. Finally, it should be noted that while only the case of Ge film electrodes with a single thickness was investigated here, the ion beam mixing approach to improving electrode adhesion strength can, in principle, be applied to other types of conversion electrodes of any arbitrary thickness via adjustment of the ion beam modification conditions. The implications of this are significant as this approach could potentially allow for the production of inexpensive, relatively thick Si film electrodes that can be cycled for a large number of cycles without decrepitation. Additionally, this work only investigated one specific ion beam modification condition and the adhesion strength of the electrode should scale with the ion dose assuming the same ion energy [18-20]. Therefore, if the electrochemical performance of the electrode scales with the adhesion strength, there should be a distinct relationship between ion dose (at a given ion energy) and electrochemical performance. Experiments are in progress to investigate this.

### SUMMARY AND CONCLUSIONS

In conclusion, it was shown for the first time that ion beam mixing enhances the strength of adhesion of Ge film electrodes to the current collector and results in a dramatic improvement in electrochemical performance. Specifically, the ion beam-mixed film electrodes exhibit stable specific capacities close to the theoretical value of Ge for a range of cycling rates and are superior to many nanoscale forms of Ge electrodes. Moreover, this approach of using ion beam modification as a means to improve Ge film electrode performance is very simple, can be readily applied to other types of conversion electrodes, and offers the potential of fabricating high capacity Li ion battery electrodes inexpensively.

References, each of which is incorporated herein by reference
[1] H. Okamoto, J. Phase Equil. Diff. 30 (2009) 118-119.
[2] J. Sangster, C. Bale, J. Phase Equilib. 19 (1998) 70-75.
[3] J. Sangster, A. Pelton, J. Phase Equilib. 18 (1997) 289-294.
[4] R. Huggins, W. Nix, Ionics 6 (2000) 57-63.
[5] P. G. Bruce, B. Scrosati, J. M. Tarascon, Angew. Chem.-Int. Edit. 47 (2008) 2930-2946.
[6] C. K. Chan, H. L. Peng, G. Liu, K. Mcllwrath, X. F. Zhang, R. A. Huggins, Y. Cui, Nature Nanotech. 3 (2008) 31-35.
[7] C. K. Chan, X. F. Zhang, Y. Cui, Nano Lett. 8 (2008) 307-309.
[8] M.-H. Park, K. Kim, J. Kim, J. Cho, Adv. Mater. 22 (2010) 415-418.
[9] K. Q. Peng, J. S. Jie, W. J. Zhang, S. T. Lee, Appl. Phys Lett. 93 (2008) 033105.
[10] M. H. Seo, M. Park, K. T. Lee, K. Kim, J. Kim, J. Cho, Energy Environ. Sci. 4 (2011) 425-428.
[11] J. Yang, M. Winter, J. O. Besenhard, Solid State Ionics 90 (1996) 281-287.
[12] J. C. Li, A. K. Dozier, Y. C. Li, F. Q. Yang, Y. T. Cheng, J. Electrochem. Soc. 158 (2011) A689-A694.
[13] J. P. Maranchi, A. F. Hepp, A. G. Evans, N. T. Nuhfer, P. N. Kumta, J. Electrochem. Soc. 153 (2006) A1246-A1253.
[14] F. Q. Yang, J. Power Sources 196 (2011) 465-469.
[15] J. E. E. Baglin, Nucl. Instrum. Methods Phys. Res. B 65 (1992) 119-128.
[16] J. E. E. Baglin, IBM J. Res. Dev. 38 (1994) 413-422.
[17] J. E. E. Baglin, G. J. Clark, Nucl. Instrum. Methods Phys. Res. B 7-8 (1985) 881-885.
[18] J. E. E. Baglin, Nucl. Instrum. Methods Phys. Res. B 65 (1992) 119-128.
[19] K. H. Chae, J. H. Joo, I. S. Choi, K. S. Kim, S. S. Kim, C. N. Whang, H. K. Kim, D. W. Moon, J. Korean Phys. Soc. 26 (1993) 612-616.
[20] L. Guzman, A. Miotello, R. Checchetto, M. Adami, Surf. Coat. Technol. 158 (2002) 558-562.
[21] N. G. Rudawski, B. L. Darby, B. R. Yates, K. S. Jones, R. G. Elliman, A. A. Volinsky, Appl. Phys Lett. 100 (2012) 083111.
[22] B. R. Appleton, O. W. Holland, D. B. Poker, J. Narayan, D. Fathy, Nucl. Instrum. Methods Phys. Res. B 7-8 (1985) 639-644.
[23] B. L. Darby, B. R. Yates, N. G. Rudawski, K. S. Jones, A. Kontos, R. G. Elliman, Thin Solid Films 519 (2011) 5962-5965.
[24] O. W. Holland, B. R. Appleton, J. Narayan, J. Appl. Phys. 54 (1983) 2295-2301.
[25] H. Huber, W. Assmann, S. A. Karamian, A. Mucklich, W. Prusseit, E. Gazis, R. Grotzschel, M. Kokkoris, E. Kossionidis, H. D. Mieskes, R. Vlastou, Nucl. Instrum. Methods Phys. Res. B 122 (1997) 542-546.
[26] R. J. Kaiser, S. Koffel, P. Pichler, A. J. Bauer, B. Amon, A. Claverie, G. Benassayag, P. Scheiblin, L. Frey, H. Ryssel, Thin Solid Films 518 (2010) 2323-2325.
[27] E. M. Lawson, K. T. Short, J. S. Williams, B. R. Appleton, O. W. Holland, O. E. Schow, Nucl. Instrum. Methods Phys. Res. 209 (1983) 303-307.
[28] L. Romano, G. Impellizzeri, M. V. Tomasello, F. Giannazzo, C. Spinella, M. G. Grimaldi, J. Appl. Phys. 107 (2010) 084314.
[29] B. Stritzker, R. G. Elliman, J. Zou, Nucl. Instrum. Methods Phys. Res. B 175 (2001) 193-196.
[30] P. A. Steinmann, H. E. Hintermann, J. Vac. Sci. Technol. A 7 (1989) 2267-2272.
[31] K. Xu, Chem. Rev. 104 (2004) 4303-4417.
[32] L. Baggetto, P. H. L. Notten, J. Electrochem. Soc. 156 (2009) A169-A175.
[33] J. Graetz, C. C. Ahn, R. Yazami, B. Fultz, J. Electrochem. Soc. 151 (2004) A698-A702.
[34] B. Laforge, L. Levan-Jodin, R. Salot, A. Billard, J. Electrochem. Soc. 155 (2008) A181-A188.
[35] H. Lee, H. Kim, S. G. Doo, J. Cho, J. Electrochem. Soc. 154 (2007) A343-A346.
[36] L. C. Yang, Q. S. Gao, L. Li, Y. Tang, Y. P. Wu, Electrochem. Commun. 12 (2010) 418-421.
[37] G. Peto, Z. F. Horvath, O. Gereben, L. Pusztai, F. Hajdu, E. Svab, Phys. Rev. B 50 (1994) 539-542.
[38] J. F. Ziegler, Nucl. Instrum. Methods Phys. Res. B 219 (2004) 1027-1036.
[39] G. M. Veith, N. J. Dudney, J. Electrochem. Soc. 158 (2011) A658-A663.
[40] A. A. Volinsky, N. R. Moody, W. W. Gerberich, Acta Mater. 50 (2002) 441-466.
[41] E. Peled, J. Electrochem. Soc. 126 (1979) 2047-2051.
[42] G. L. Cui, L. Gu, N. Kaskhedikar, P. A. van Aken, J. Maier, Electrochim. Acta 55 (2010) 985-988.
[43] R. A. DiLeo, M. J. Ganter, R. P. Raffaelle, B. J. Landi, J. Mater. Res. 25 (2010) 1441-1446.
[44] J. W. Choi, J. McDonough, S. Jeong, J. S. Yoo, C. K. Chan, Y. Cui, Nano Lett. 10 (2010) 1409-1413.
[45] K. Kang, H. S. Lee, D. W. Han, G. S. Kim, D. Lee, G. Lee, Y. M. Kang, M. H. Jo, Appl. Phys Lett. 96 (2010) 053110.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment, the term “about” can include traditional rounding according to how the numerical value determined. In addition, the phrase “about ‘x’ to ‘y’” includes “about ‘x’ to about ‘y’”.

Many variations and modifications may be made to the above-described embodiments. All such modifications and variations are intended to be included herein within the scope of this disclosure and protected by the following claims.

At least the following is claimed:

1. A structure, comprising:
a film disposed on the substrate, wherein one or more areas of the film have been ion beam-mixed to form an ion beam-mixed film.

2. The structure of claim 1, wherein the film is selected from the group consisting of: a germanium film, a silicon film, a germanium-silicon film, sulfur film, sulfur compound based film, vandium based oxide film, a MF_{x.} film, where M=Fe, Cu, Na, x is 1 to 3.

3. The structure of claim 1, wherein the film is a germanium film.

4. The structure of claim 3, wherein the germanium film has a thickness of about 100 nm to 2000 nm.

5. The structure of claim 3, wherein the ion beam-mixed film is an ion beam-mixed germanium film.

6. The structure of claim 5, wherein the ion beam-mixed germanium film has a thickness of about 0.01 μm and 10 μm.

7. The structure of claim 6, wherein the substrate is a material selected from: Ni foil and Ni/Fe foil.

8. The structure of claim 1, wherein the substrate is a material selected from: Al, Ni, Fe, Cu, stainless steel, a non-lithiating material, and a combination thereof.

9. A method of making a structure, comprising:
providing a structure having a film disposed on a substrate; and
forming an ion beam-mixed film by subjecting the film to ion beam implantation.

10. The method of claim 9, wherein the film is selected from the group consisting of: a germanium film, a silicon film, and a germanium-silicon film.

11. The method of claim 10, wherein the film is a germanium film.

12. The method of claim 11, wherein the germanium film has a thickness of about 100 nm to 400 nm.

13. The method of claim 11, wherein the ion beam-mixed film is an ion beam-mixed germanium film.

14. The method of claim 13, wherein the ion beam-mixed germanium film has a thickness of about 0.01 μm and 10 μm.

15. The method of claim 15, wherein the substrate is a material selected from: Ni foil and Ni/Fe foil.

16. The method of claim 11, wherein the substrate is a material selected from: Al, Ni, Fe, Cu, stainless steel, a non-lithiating material, and a combination thereof.

17. The method of claim 11, wherein the ion beam implantation is a Ge⁺ ion beam implantation.

18. The method of claim 17, wherein the Ge⁺ ion beam implantation conditions are about 260 keV Ge⁺ ions, an ion dose of about 1.0×10¹⁶ cm⁻², about 0° tilt and 0° twist angles, and implant temperature is about 77 K.

19. The method of claim 1, wherein the ion beam implantation has an implant energy of about 1 keV to 10 MeV, wherein the ion dose is about 1.0×10¹³ to 1.0×10¹⁷ cm⁻² and wherein the implant temperature is about 77 to 600 K.
